(19) United States
(12) Patent Application Publication
(10) Pub. No.: US 2007/0278488 A1
(43) Pub. Date: Dec. 6, 2007

(54) Electro-optical device and electronic apparatus

(75) Inventors: Yukiya Hirabayashi, Suwa-shi (JP); Yutaka Sano, Tottori-shi (JP)

Correspondence Address: OLIFF & BERRIDGE, PLC, P.O. BOX 19928, ALEXANDRIA, VA, 22320, US

(73) Assignee: EPSON IMAGING DEVICES CORPORATION, AZUMINO-SHI (JP)

(21) Appl. No.: 11/785,209

(22) Filed: Apr. 16, 2007

(30) Foreign Application Priority Data
Jun. 1, 2006 (JP) 2006-153107

(51) Int. Cl. H01L 29/04

(52) U.S. Cl. 257/59

(57) ABSTRACT

An electro-optical device includes pixel regions arranged at intersections of a plurality of data lines and a plurality of scanning lines on an element substrate. A sensor element, a sensor signal line for outputting a signal from the sensor element, and a common wiring line are disposed at an end of a region on the element substrate in which the pixel regions are arranged. A switching element is disposed between the sensor signal line and the common wiring line. A control wiring line for supplying a signal setting the switching element to be in a non-conducting state is disposed for the switching element.

### BACKGROUND

1. Technical Field

The present invention relates to electro-optical devices and electronic apparatuses. More specifically, the invention relates to an electro-optical device in which signal lines are electrically connected to a common wiring line via electrostatic protection elements on an element substrate, and to an electronic apparatus including the electro-optical device.

2. Related Art

Of electro-optical devices such as liquid crystal devices, electroluminescent display devices, and image pickup devices, for example, an active-matrix liquid crystal device uses an element substrate 10 shown in FIG. 16A. On the element substrate 10, a plurality of data lines 6a and a plurality of scanning lines 3a extend orthogonally to each other, and a plurality of pixel regions 1e are arranged at intersections of the data lines 6a and the scanning lines 3a.

An insulating substrate is used as the base of the element substrate 10. Thus, a structure for preventing pixel transistors 1c arranged in the pixel regions 1e from being damaged by static electricity generated on the element substrate 10 during the manufacturing process is adopted. That is, for example, as disclosed in JP-A-2004-303925, on the element substrate 10, the data lines 6a and the scanning lines 3a are electrically connected to a common wiring line VCOM via electrostatic protection elements each formed of a bidirectional diode element Di, and the common wiring line VCOM is electrically connected to a guard ring via an electrostatic protection element formed of the bidirectional diode element Di. As shown in FIG. 16B, the bidirectional diode element Di includes semiconductor elements 1s each including a pair of source and drain electrodes, a semiconductor layer having a channel region, and a gate electrode facing the channel region with a gate insulating film disposed therebetween so that the semiconductor elements 1s are electrically connected in opposite directions to each other. In each of the semiconductor elements 1s, one of the source and drain electrodes is connected to the gate electrode.

The assignee of the invention proposes that, as shown in FIG. 17, sensor elements 1h and a sensor signal line 1j are disposed on the element substrate 10 to detect a state quantity such as illuminance or temperature so that the display operation of the liquid crystal device can be controlled according to the detected state quantity. In this case, it is preferable that the sensor signal line 1j also be electrically connected to the common wiring line VCOM in order to protect the sensor elements 1h against static electricity.

However, if the sensor signal line 1j is electrically connected to the common wiring line VCOM, there arises a problem in that signals output from the sensor elements 1h are leaked into the common wiring line VCOM. One conceivable solution is that, as shown in FIG. 17, the sensor signal line 1j is electrically connected to the common wiring line VCOM via an electrostatic protection element formed of a bidirectional diode element Di. If, for example, the bidirectional diode element Di shown in FIG. 16B is used as an electrostatic protection element for the sensor signal line 1j, the leakage current of the bidirectional diode element Di affects the signals output from the sensor elements 1h, resulting in low detection accuracy. The low-detection-accuracy problem is solved by, as disclosed in JP-A-2004-303925, separating the bidirectional diode element Di at the final stage of the manufacturing process. However, the additional separating step decreases the productivity, and the bidirectional diode element Di may not be separated depending on the position of the bidirectional diode element Di.

### SUMMARY

An advantage of some aspects of the invention is that it provides an electro-optical device in which sensor elements defined on an element substrate can be protected against static electricity and high-accuracy detection can be performed using the sensor elements, and an electronic apparatus including the electro-optical device.

According to an aspect, the invention provides an electro-optical device including pixel regions arranged at intersections of a plurality of data lines and a plurality of scanning lines on an element substrate, wherein a sensor element, a sensor signal line for outputting a signal from the sensor element, and a common wiring line are disposed at an end of a region on the element substrate in which the pixel regions are arranged, a switching element is disposed between the sensor signal line and the common wiring line, and a control wiring line for supplying a signal setting the switching element to be in a non-conducting state is disposed for the switching element.

In this case, a bidirectional diode element electrically connected in series with the switching element may be disposed between the sensor signal line and the common wiring line.

According to the aspect of the invention, since the sensor element is disposed on the element substrate, for example, the illuminance of the environment where the electro-optical device is placed can be detected using the sensor element, and an image can be displayed on the electro-optical device under conditions corresponding to the detected illuminance. Further, since the sensor signal line through which a signal is output from the sensor element is electrically connected to the common wiring line via the switching element, static electricity generated on the element substrate during the manufacturing process of the electro-optical device or the like can be discharged to the common wiring line via the switching element. The sensor element can therefore be protected against static electricity. Since the control wiring line is disposed for the switching element, a switching signal is applied from the control wiring line to ensure that the switching element can be brought into a non-conducting state. Accordingly, the common wiring line, the leakage current of the bidirectional diode element, and the like do not affect the signal output from the sensor element. Even in a case where the sensor element disposed on the element substrate is protected against static electricity, therefore, high-accuracy detection can be performed using the sensor element.

The electro-optical device may be configured such that the switching element is a semiconductor element including a source electrode, a drain electrode, a semiconductor layer having a channel region, and a gate electrode facing the channel region with a gate insulating film disposed therebetween, the gate electrode being electrically connected to the control wiring line, and that the gate electrode is a floating-gate electrode that is connected to each of the source electrode and the drain electrode via a parasitic capacitance. With this structure, when a high voltage caused by static electricity is applied between the source electrode and the drain electrode, the high voltage applied between the source electrode and the drain electrode is divided by a parasitic capacitance generated between the source electrode and the gate electrode and a parasitic capacitance generated between the drain electrode and the gate electrode, and the divided voltage is applied to the gate electrode. As a result, the switching element is brought into a conducting state. Therefore, static electricity or the like can be discharged to the common wiring line. Further, the switching element can be finished at a relatively early stage of the manufacturing process, and the sensor element can be protected against static electricity at the relatively early stage of the manufacturing process.

The electro-optical device may be configured such that the switching element is a semiconductor element including a source electrode, a drain electrode, a semiconductor layer having a channel region, and a gate electrode facing the channel region with a gate insulating film disposed therebetween, the gate electrode being electrically connected to the control wiring line, and that the gate electrode is a floating-gate electrode that is electrically connected to each of the source electrode and the drain electrode via a capacitor element. With this structure, when a high voltage caused by static electricity is applied between the source electrode and the drain electrode, the high voltage applied between the source electrode and the drain electrode is divided by a capacitor element generated between the source electrode and the gate electrode and a capacitor element generated between the drain electrode and the gate electrode, and the divided voltage is applied to the gate electrode. As a result, the switching element is brought into a conducting state. Therefore, static electricity or the like can be discharged to the common wiring line. Further, the switching element can be finished at a relatively early stage of the manufacturing process, and the sensor element can be protected against static electricity at the relatively early stage of the manufacturing process.

The capacitor element in the switching element may be formed by arranging each of the source electrode and the drain electrode so as to face the gate electrode with an insulation film disposed therebetween.

The electro-optical device may be configured such that the sensor element includes a semiconductor element including a source electrode, a drain electrode, a semiconductor layer having a channel region, and a gate electrode facing the channel region with the gate insulating film disposed therebetween, and a capacitor element electrically connected to the semiconductor element, and that after the capacitor element is charged, a state quantity is detected on the basis of a characteristic of discharging performed via the semiconductor element of the sensor element.

It is preferable that the source electrode, the drain electrode, the semiconductor layer, and the gate electrode of the switching element are made of the same materials as the materials of the source electrode, the drain electrode, the semiconductor layer, and the gate electrode of the sensor element, respectively, and that a pair of layers between which the source electrode, the drain electrode, the semiconductor layer, or the gate electrode of the switching element is disposed is the same as a pair of layers between which the source electrode, the drain electrode, the semiconductor layer, or the gate electrode of the sensor element is disposed, respectively. With this structure, the switching element and the sensor element can be fabricated using a common manufacturing process.

The channel region of the sensor element can be formed of an amorphous silicon film, a polycrystalline polysilicon film fabricated in a low-temperature process, a polycrystalline polysilicon film fabricated in a high-temperature process, or the like. Of these semiconductor films, the amorphous silicon film is used as the channel region of the sensor element, thereby realizing a sensor element having high sensitivity to the illuminance or the like.

The sensor element may be, for example, an optical sensor element. Alternatively, the sensor element may be a temperature sensor element.

It is preferable that each of the pixel regions includes a pixel transistor including a source electrode, a drain electrode, a semiconductor layer having a channel region, and a gate electrode facing the channel region with the gate insulating film disposed therebetween, and a pixel electrode electrically connected to the pixel transistor, that the source electrodes, the drain electrodes, the semiconductor layers, and the gate electrodes of the pixel transistors are made of the same materials as the materials of the source electrode, the drain electrode, the semiconductor layer, and the gate electrode of the switching element, respectively, and that a pair of layers between which the source electrodes, the drain electrodes, the semiconductor layers, or the gate electrodes of the pixel transistors are disposed is the same as a pair of layers between which the source electrode, the drain electrode, the semiconductor layer, or the gate electrode of the switching element is disposed, respectively. With this structure, the pixel transistors and the switching element can be fabricated using a common manufacturing process.

According to another aspect, the invention provides an electronic apparatus including the above-described electro-optical device. The electronic apparatus may be a mobile phone or a mobile computer.

### BRIEF DESCRIPTION OF THE DRAWINGS

The invention will be described with reference to the accompanying drawings, wherein like numbers reference like elements.

FIG. 1A is a plan view of a liquid crystal device (electro-optical device) according to a first embodiment of the invention and components incorporated therein as viewed from the side of a counter substrate.

FIG. 1B is a cross-sectional view taken along a line IB-IB of FIG. 1A.

FIG. 2A is a block diagram showing the electrical structure of an element substrate of the liquid crystal device shown in FIGS. 1A and 1B.

FIG. 2B is a block diagram showing the structure of a sensor-drive IC of the liquid crystal device shown in FIGS. 1A and 1B.

FIG. 3A is a block diagram showing the electrical structure of a sensor element and the like before an external circuit is mounted on the element substrate of the liquid crystal device shown in FIGS. 1A and 1B.

FIG. 3B is a block diagram showing the electrical structure of the sensor element and the like after the external circuit has been mounted.

FIG. 4A is a plan view showing three pixel regions arranged on the element substrate used in the liquid crystal device shown in FIGS. 1A and 1B.

FIG. 4B is a cross-sectional view taken along a line IVB-IVB of FIG. 4A.

FIGS. 5A and 5B are an equivalent circuit diagram and a plan view of a bidirectional diode disposed on the element substrate used in the liquid crystal device shown in FIGS. 1A and 1B, respectively.

FIG. 5C is a cross-sectional view taken along a line VC-VC of FIG. 5B.

FIGS. 6A and 6B are an equivalent circuit diagram and a plan view of a switching element disposed on the element substrate used in the liquid crystal device shown in FIGS. 1A and 1B, respectively.

FIG. 6C is a cross-sectional view taken along a line VIC-VIC of FIG. 6B.

FIG. 6D is a graph showing the I-V characteristic of the switching element.

FIGS. 7A and 7B are an equivalent circuit diagram and a plan view of a sensor element disposed on the element substrate used in the liquid crystal device shown in FIGS. 1A and 1B, respectively.

FIG. 7C is a cross-sectional view taken along a line VIIC-VIIC of FIG. 7B.

FIGS. 8A to 8D are graphs showing the discharge characteristic in the sensor element shown in FIGS. 7A to 7C.

FIG. 8E is a graph showing the relationship between the time constant and the illuminance in the sensor element shown in FIGS. 7A to 7C.

FIG. 9A is a block diagram showing the electrical structure of a sensor element and the like before an external circuit is mounted on an element substrate of a liquid crystal device according to a modification of the first embodiment of the invention.

FIG. 9B is a block diagram showing the electrical structure of the sensor element and the like after the external circuit has been mounted.

FIG. 10A is a block diagram showing the electrical structure of a sensor element and the like before an external circuit is mounted on an element substrate of a liquid crystal device according to a second embodiment of the invention.

FIG. 10B is a block diagram showing the electrical structure of the sensor element and the like after the external circuit has been mounted.

FIGS. 11A and 11B are an equivalent circuit diagram and a plan view of a switching element disposed on the element substrate of the liquid crystal device shown in FIGS. 10A and 10B, respectively.

FIG. 11C is a cross-sectional view taken along a line XIC-XIC of FIG. 11B.

FIG. 12A is a block diagram showing the electrical structure of a sensor element and the like before an external circuit is mounted on an element substrate of a liquid crystal device according to a modification of the second embodiment of the invention.

FIG. 12B is a block diagram showing the electrical structure of the sensor element and the like after the external circuit has been mounted.

FIG. 13 is a block diagram showing the electrical structure of an element substrate according to another embodiment of the invention.

FIG. 14 is a block diagram showing the electrical structure of a sensor element and the like disposed on the element substrate shown in FIG. 13.

FIGS. 15A to 15C are schematic diagrams of electronic apparatuses including a liquid crystal device according to the invention.

FIGS. 16A and 16B are block diagrams showing the electrical structure of an element substrate used in a liquid crystal device of the related art.

FIG. 17 is a block diagram showing a reference example in which sensor elements are incorporated in the liquid crystal device of the related art.

### DESCRIPTION OF EXEMPLARY EMBODIMENTS

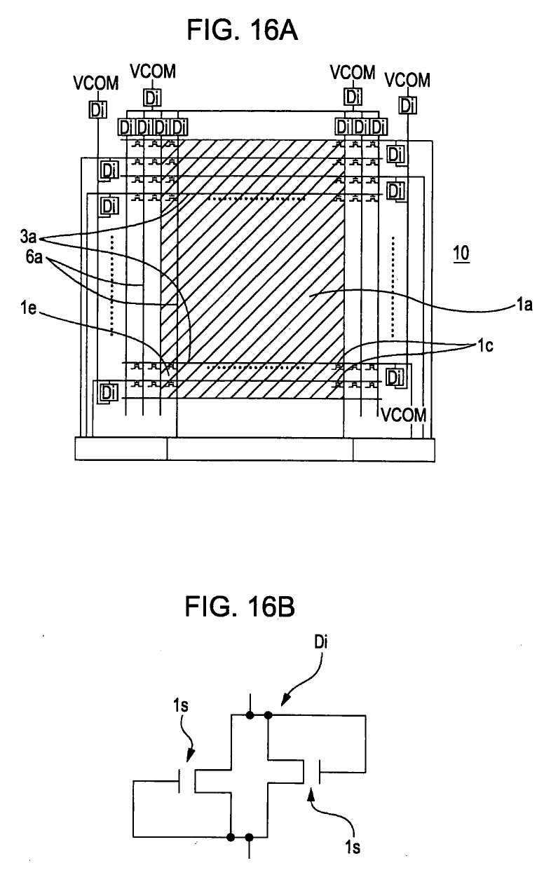

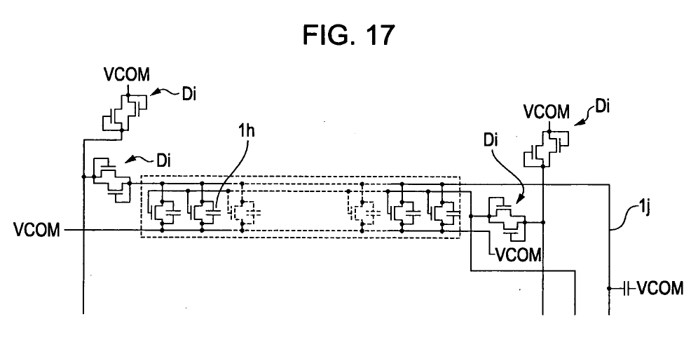

Exemplary embodiments of the invention will now be described with reference to the drawings. In the figures used in conjunction with the following embodiments, layers and parts are illustrated in different scales so as to allow recognition of the layers and parts in the figures. In the following description, parts having the same or similar functions to those shown in FIGS. 16A to 17 are represented by the same reference numerals so as to clarify the correspondences therebetween. In the following description, further, a pixel transistor, a bidirectional diode element, a switching element, and a sensor element have a MIS-type semiconductor element structure including a pair of source and drain electrodes. When the pair of source and drain electrodes is separately identified, for the convenience of description, the source and drain electrodes are distinguished by focusing on the direction in which a current flows in a channel region for a certain period.

### First Embodiment

### Overall Structure of Liquid Crystal Device

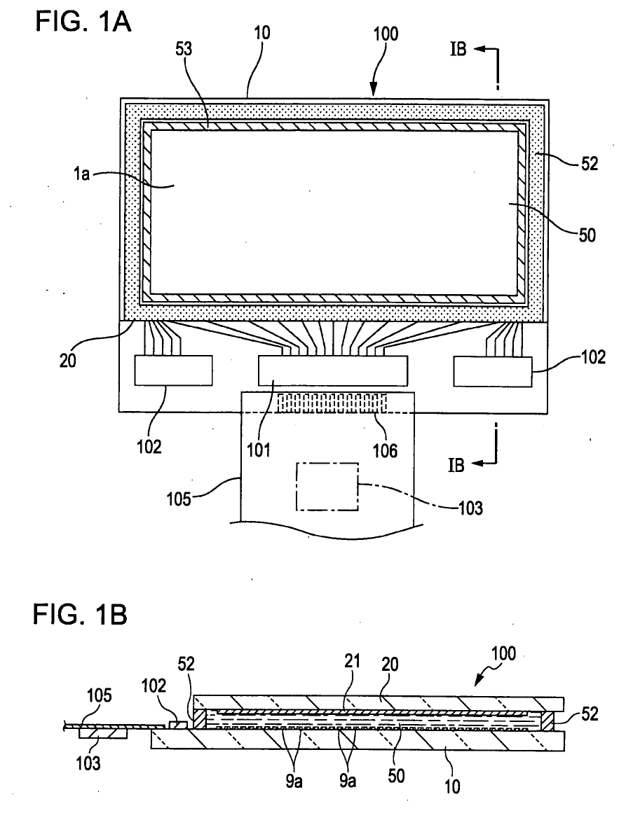

FIG. 1A is a plan view of a liquid crystal device (electro-optical device) 100 according to a first embodiment of the invention and components incorporated therein as viewed from the side of a counter substrate, and FIG. 1B is a cross-sectional view taken along a line IB-IB of FIG. 1A. In FIGS. 1A and 1B, the liquid crystal device 100 according to the first embodiment is a transmissive active-matrix liquid crystal device of the TN (Twisted Nematic) mode, ECB (Electrically Controlled Birefringence) mode, or VAN (Vertical Aligned Nematic) mode. In the liquid crystal device 100, an element substrate 10 and a counter substrate 20 are bonded to each other through a seal 52, and a liquid crystal 50 is held between the element substrate 10 and the counter substrate 20.

Drive ICs 101 and 102 including a scanning line driving circuit and a data line driving circuit are mounted on the element substrate 10 so as to be located in an edge region defined outside the seal 52, and a mounting terminal 106 is disposed along a side of the element substrate 10. The seal 52 is an adhesive made of a photocurable resin, a thermosetting resin, or the like for bonding the element substrate 10 and the counter electrode 20 at the peripheries thereof, and is mixed with a gap material such as glass fibers or glass beads for ensuring a predetermined distance between the substrates 10 and 20. Although not shown in FIGS. 1A and 1B, the seal 52 is partially cut out to form a liquid-crystal-injection port, which is sealed by a sealing agent after the liquid crystal 50 is injected through the liquid-crystal-injection port.

The element substrate 10 includes pixel transistors, described below, and pixel electrodes 9a arranged in a matrix, and an alignment film (not shown) is overlaid on the pixel electrodes 9a. The counter substrate 20 includes a frame-shaped area 53 (not shown in FIG. 1B) made of a light-shielding material along the inner periphery of the seal 52, and an image display region 1a defined by the inner surface of the frame-shaped area 53. A light-shielding film called black matrix or black stripe (not shown) is disposed on the counter substrate 20 so as to face the vertical and horizontal boundaries of pixel regions, and a counter electrode 21 and an alignment film (not shown) are disposed on the top layer of the light-shielding film. Although not shown in FIG. 1B, RGB color filters with protection films are arranged on the counter substrate 20 so as to face the pixel regions defined on the element substrate 10. The liquid crystal device 100 can therefore be used as a color display device of an electronic apparatus such as a mobile computer, a mobile phone, and a liquid crystal television set.

At an edge of the element substrate 10, a flexible wiring substrate 105 is connected to the mounting terminal 106. The flexible wiring substrate 105 has mounted thereon a sensor-drive IC 103 including a sensor control circuit for controlling sensor elements, described below.

While the drive ICs 101 and 102 are illustrated as three units including a scanning line driving circuit and data line driving circuits, respectively, by way of example, the drive ICs 101 and 102 may be formed of a single drive IC including both a scanning line driving circuit and a data line driving circuit. In the first embodiment, the sensor-drive IC 103 is mounted on the flexible wiring substrate 105. Alternatively, the sensor-drive IC 103 may be mounted on the element substrate 10, or the sensor control circuit and the like may be built in the same IC as the scanning line driving circuit and the data line driving circuit.

### Overall Structure of Element Substrate 10

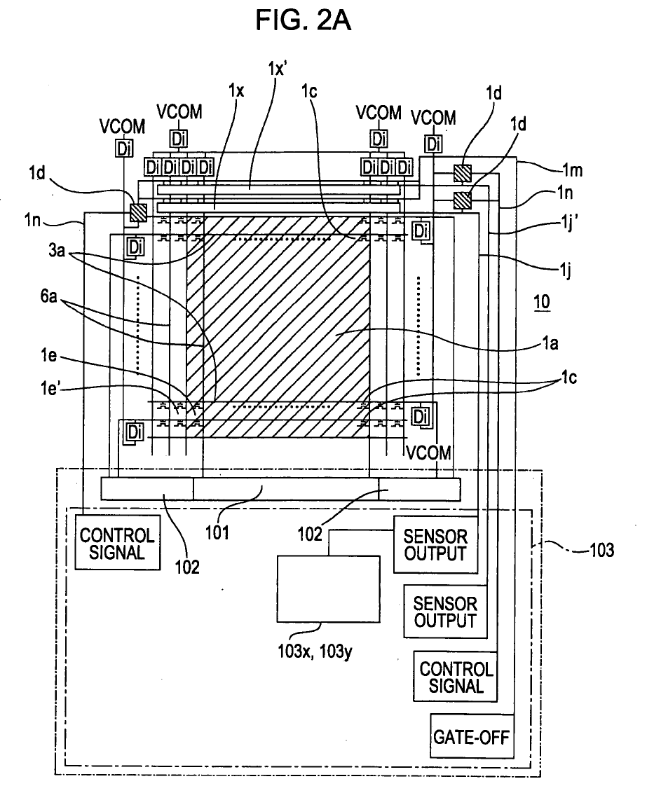

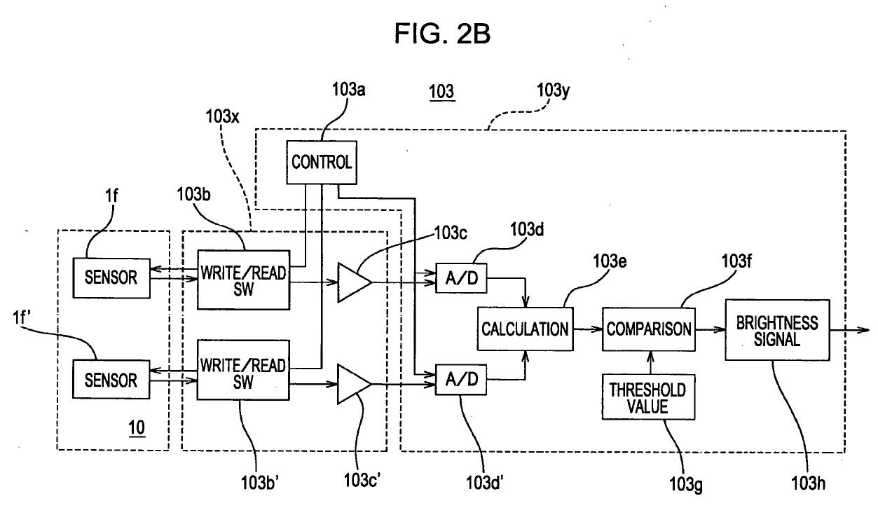

FIG. 2A is a block diagram showing the electrical structure of the element substrate 10 of the liquid crystal device 100 shown in FIGS. 1A and 1B, and FIG. 2B is a block diagram showing the structure of the sensor-drive IC 103.

As shown in FIG. 2A, on the element substrate 10, a plurality of data lines (source lines) 6a and scanning lines (gate lines) 3a are arranged in a region corresponding to the image display region 1a (as shown by shading) so that the data lines 6a and the scanning lines 3a orthogonally intersect each other, and a plurality of pixel regions 1e are arranged at the intersections of the data lines 6a and the scanning lines 3a. Pixel transistors 1c for controlling the alignment of the liquid crystal are disposed in the pixel regions 1e, and are formed of MIS-type semiconductor elements (thin-film transistors). Sources of the pixel transistors 1c are electrically connected to the data lines 6a, and gates of the pixel transistors 1c are electrically connected to the scanning lines 3a. Dummy pixel regions 1e′ having the same structure as the pixel regions 1e are disposed around the image display region 1a. The data lines 6a and the scanning lines 3a extend from the drive ICs 101 and 102, respectively. The element substrate 10 may include a capacitor line (not shown) for forming a hold capacitor for each pixel. If hold capacitors are configured between the adjacent scanning lines 3a, no capacitor lines are required.

The base of the element substrate 10 is formed of an insulating substrate such as a glass substrate. If static electricity is generated in the data lines 6a or the scanning lines 3a during the manufacturing process, the pixel transistors 1c may be damaged by the static electricity. For example, when the element substrate 10 is exposed to plasma during film deposition or etching of the element substrate 10 or when the element substrate 10 is brought into contact with a conveying arm during conveying, the element substrate 10 is electrostatically charged, and static electricity may be generated in the data lines 6a or the scanning lines 3a. A wiring called a guard ring (not shown) is disposed around a region to be cut out to form the element substrate 10 from a large-size substrate. The guard ring is connected to a common wiring line VCOM defined on the element substrate 10 via a bidirectional diode element Di, and electrostatic protection elements each formed of the bidirectional diode element Di are arranged between the common wiring line VCOM and the data lines 6a and between the common wiring line VCOM and the scanning lines 3a. Thus, static electricity generated in the data lines 6a and the scanning lines 3a during the manufacturing process of the element substrate 10 can be discharged to the common wiring line VCOM via the bidirectional diode elements Di, and static electricity generated in the common wiring line VCOM can be discharged to the guide ring via the bidirectional diode element Di. Accordingly, the pixel transistors 1c can be protected against static electricity in the manufacturing process of the element substrate 10. Although the guide ring has been separated from the element substrate 10 when the element substrate 10 is used in the liquid crystal device 100, the bidirectional diode elements Di still remain on the element substrate 10. As described below, each of the bidirectional diode elements Di has a structure in which two MIS-type semiconductor elements 1s each formed of a MIS-type diode whose drain and gate are connected are connected in parallel in opposite directions to each other. Due to the easy control of a threshold voltage and relatively low leakage current, the bidirectional diode elements Di still remaining on the element substrate 10 at the stage of fabrication of the liquid crystal device 100 have no problem with the display operation and the like.

### Detailed Structure of Element Substrate 10

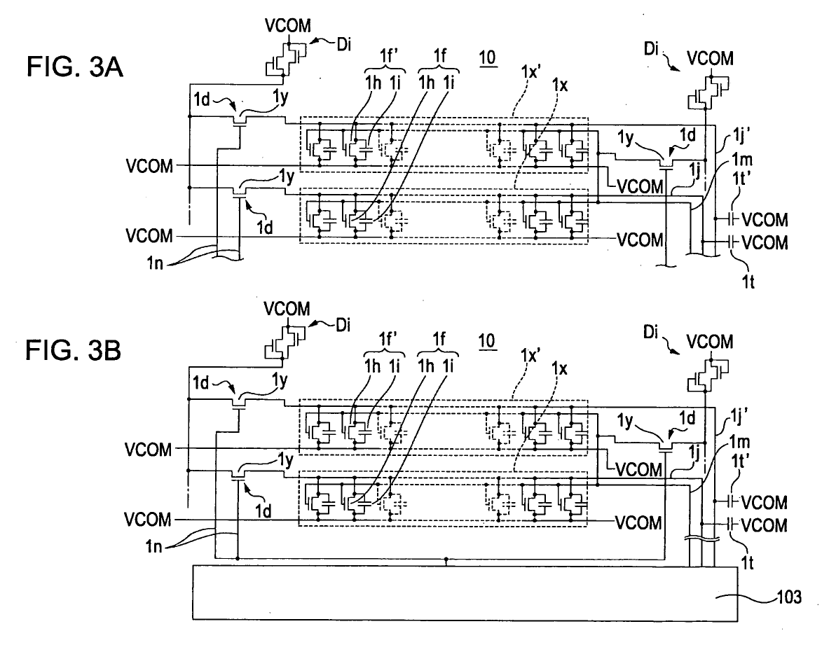

FIGS. 3A and 3B are block diagrams showing the electrical structure of sensor elements and the like disposed on the element substrate 10 of the liquid crystal device 100 shown in FIGS. 1A and 1B. FIG. 3A shows the state before an external circuit is mounted on the element substrate 10, and FIG. 3B shows the structure after the external circuit has been mounted.

As shown in FIGS. 2A, 3A, and 3B, the element substrate 10 used in the liquid crystal device 100 of the first embodiment includes a sensor-element forming region 1x including a plurality of sensor elements 1f for detecting a state quantity such as illuminance. The sensor-element forming region 1x is disposed at an edge of the pixel display region 1a (at an edge of the region where the pixel regions 1e are arranged) so as to extend along one side of the pixel display region 1a. A reference-sensor-element forming region 1x′ including a plurality of reference sensor elements 1f′ used for comparison in the detection process using the sensor elements if is disposed outside the sensor-element forming region 1x. While external light reaches the sensor-element forming region 1x, the reference-sensor-element forming region 1x′ is covered with the light-shielding film defined on the counter substrate 20 and a frame of the liquid crystal device 100, and external light does not reach the reference-sensor-element forming region 1x′.

Each of the sensor elements 1f and 1f′ includes an MIS-type semiconductor element 1h and a capacitor element 1i electrically connected in parallel with the semiconductor element 1h. The structure of the sensor elements 1f and 1f′ is described in detail below.

The element substrate 10 further includes, at the edge of the region where the pixel regions 1e are arranged, sensor signal lines 1j and 1j′ for outputting signals from first electrodes (the drain electrodes) of the pairs of source and drain electrodes of the sensor elements 1f and 1f′. The sensor signal lines 1j and 1j′ are electrically connected to the sensor-drive IC 103. The sensor signal lines 1j and 1j′ are also electrically connected to the common wiring line VCOM via noise filter elements 1t and 1t′. each formed of a capacitor, respectively.

The element substrate 10 further includes a common gate-off wiring line 1m extending from the sensor-drive IC 103 toward the sensor-element forming region 1x and the reference-sensor-element forming region 1x′. The gate-off wiring line 1m is branched midway and electrically connected to gate electrodes of the sensor elements 1f disposed in the sensor-element forming region 1x and gate electrodes of the reference sensor elements 1f′ disposed in the reference-sensor-element forming region 1x′. Second electrodes (the source electrodes) of the pairs of source and drain electrodes of the sensor elements 1f and 1f′ are electrically connected to the common wiring line VCOM.

On the element substrate 10 with the above-described structure, electrostatic protection elements each formed of the bidirectional diode element Di are disposed at the edge of the region where the pixel regions 1e are arranged, and are arranged between the sensor signal lines 1j and 1j′ and the common wiring line VCOM for protecting the sensor elements 1f and 1f′ against static electricity. An electrostatic protection element formed of the bidirectional diode element Di is further arranged between the gate-off wiring line 1m and the common wiring line VCOM. On the element substrate 10, further, a switching element 1d connected in series with the bidirectional diode element Di is arranged between the sensor signal lines 1j and 1j′ and the common wiring line VCOM. A switching element 1d connected in series with the bidirectional diode element Di is further arranged between the gate-off wiring line 1m and the common wiring line VCOM.

Each of the switching elements 1d includes a MIS-type semiconductor element 1y, the structure of which are described in detail below. The semiconductor element 1y is a floating-gate transistor whose source and drain electrodes and gate electrode are not short-circuited with each other.

The element substrate 10 further includes a control wiring line 1n for supplying a gate voltage setting the semiconductor elements 1y of the switching elements 1d to be in a non-conducting state to the gate electrodes of the semiconductor elements 1y. The control wiring line 1n extends from the sensor-drive IC 103, and is electrically connected to the gate electrodes of the semiconductor elements 1y.

As shown in FIG. 2B, the sensor-drive IC 103 includes an input control unit 103x and a signal processing unit 103y for performing signal processing and the like on the sensor elements 1f and 1f′. The input control unit 103x allows the sensor elements 1f and 1f′ to output signals under control of a control unit 103a such as a central processing unit (CPU). The signal processing unit 103y processes the signals output from the sensor elements 1f and 1f′. The input control unit 103x further includes switch circuits 103b and 103b′ for switching the signals input from the sensor elements 1f and 1f′, and amplifier circuits 103c and 103c′ for amplifying the sensor outputs input via the switch circuits 103b and 103b′. The signal processing unit 103y includes analog-to-digital (A/D) converter circuits 103d and 103d′ for performing analog-to-digital conversion on the sensor outputs, a calculation circuit 103e for performing subtraction between the outputs from the reference sensor elements 1f′ and the outputs from the sensor elements 1f, a comparator circuit 103f for comparing the sensor signals obtained by the calculation circuit 103e with a threshold value 103g, and a signal output unit 103h for determining brightness signals (illuminance signals) on the basis of the comparison results of the comparator circuit 103f and outputting the results.

### Structure of Pixel Transistors 1c

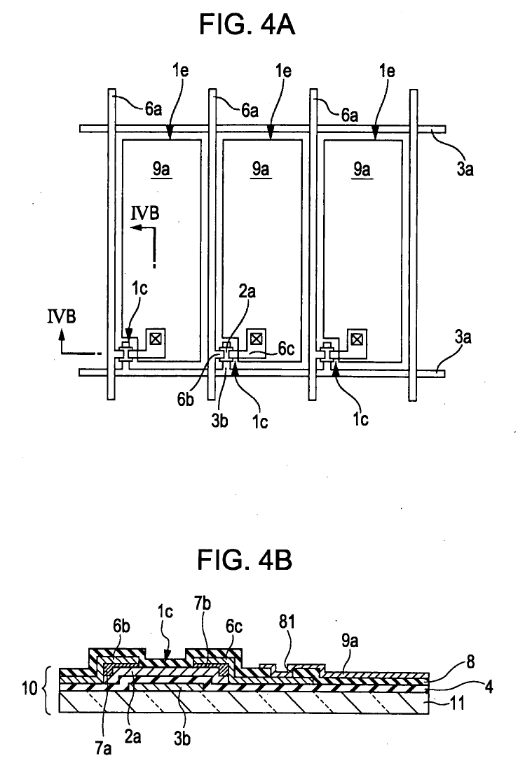

FIG. 4A is a plan view of three of the pixel regions 1e defined on the element substrate 10, and FIG. 4B is a cross-sectional view taken along a line IVB-IVB of FIG. 4A. As shown in FIG. 4A, each of the pixel regions 1e defined by the data lines 6a and the scanning lines 3a includes a semiconductor layer 2a having a channel region of the pixel transistor 1c formed of a bottom-gate thin-film transistor. A gate electrode 3b is formed of a projecting portion of each of the scanning lines 3a. A source electrode 6b, which is a portion of each of the data lines 6a, overlaps at the source-side end of each of the semiconductor layers 2a, and a drain electrode 6c overlaps at the drain-side end thereof. The pixel electrodes 9a are electrically connected to the drain electrodes 6c via contact holes 81.

The cross-section of each of the pixel transistors 1c having the above-described structure is shown in FIG. 4B. First, the scanning line 3a (the gate electrode 3b) is disposed on an insulating substrate 11 formed of a glass substrate or a quartz substrate. A gate insulating film 4 is disposed on the top layer of the gate electrode 3b. The semiconductor layer 2a having the channel region of the pixel transistor 1c is disposed on the top layer of the gate insulating film 4 so as to partially overlap the gate electrode 3b. An ohmic contact layer 7a formed of a doped silicon film and the source electrode 6b are laminated on the top layer of the source region of the semiconductor layer 2a, and an ohmic contact layer 7b formed of a doped silicon film and the drain electrode 6c are laminated on the top layer of the drain region of the semiconductor layer 2a.

The gate insulating film 4 is formed of, for example, a silicon nitride film. The scanning line 3a is, for example, a multi-layer film formed of an aluminum alloy film and a molybdenum film. The semiconductor layer 2a is formed of, for example, an amorphous silicon film, and each of the ohmic contact layers 7a and 7b is formed of, for example, an n⁺ amorphous silicon film doped with phosphorus. The data line 6a (the source electrode 6b) and the drain electrode 6c have a three-layer structure in which, for example, a molybdenum film, an aluminum film, and a molybdenum film are laminated in the stated order from the bottom to the top.

A passivation film 8 (protection film/interlayer insulation film) is disposed on the top layer of the source electrode 6b and the drain electrode 6c. The passivation film 8 is formed of, for example, a silicon nitride film. The pixel electrode 9a is disposed on the top layer of the passivation film 8, and is electrically connected to the drain electrode 6c via the contact hole 81 defined in the passivation film 8. The pixel electrode 9a is formed of, for example, an indium tin oxide (ITO) film.

### Structure of Bidirectional Diode Element Di

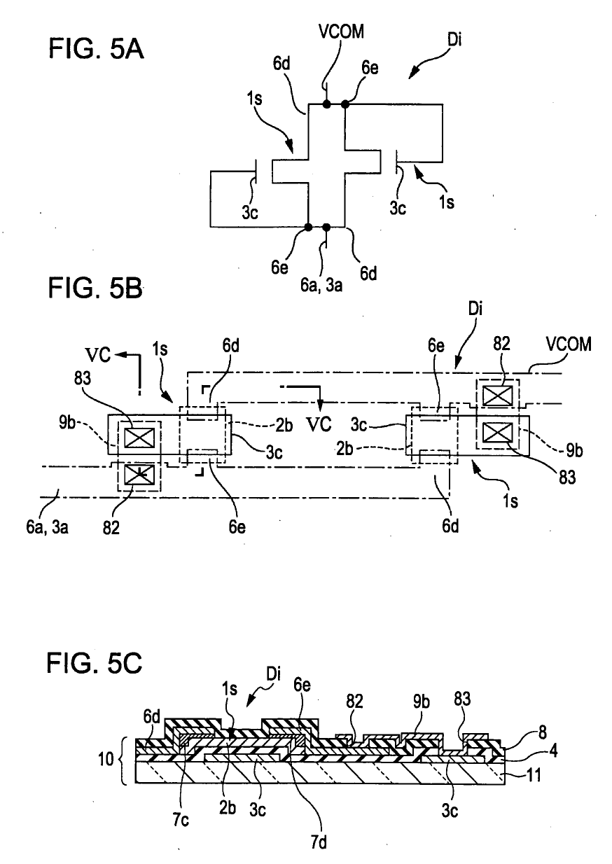

FIGS. 5A and 5B are an equivalent circuit diagram and a plan view of each of the bidirectional diodes Di disposed on the element substrate 10, respectively, and FIG. 5C is a cross-sectional view taken along a line VC-VC of FIG. 5B. As shown in FIGS. 5A, 5B, and 5C, the bidirectional diode element Di includes two MIS-type semiconductor elements 1s each including a pair of source and drain electrodes 6d and 6e, a semiconductor layer 2b having a channel region, and a gate electrode 3c facing the channel region with the gate insulating film 4 disposed therebetween so that the two MIS-type semiconductor elements 1s are electrically connected in parallel in opposite directions to each other. Each of the semiconductor elements 1s has a structure in which the drain electrode 6e in the pair of source and drain electrodes 6d and 6e is connected to the gate electrode 3c. The drain electrode 6e of one of the semiconductor elements 1s and the source electrode 6d of the other semiconductor element 1s are connected to the data line 6a or the scanning line 3a, and the source electrode 6d of the one semiconductor element 1s and the drain electrode 6e of the other semiconductor element 1s are connected to the common wiring line VCOM.

In the bidirectional diode element Di with the above-described structure, the pair of semiconductor elements 1s has the same structure. The cross-sectional structure of the semiconductor elements 1s will be described with reference to FIG. 5C. As shown in FIG. 5C, in the bidirectional diode element Di, as in each of the pixel transistors 1c, the gate electrode 3c of each of the semiconductor elements 1s is disposed on the insulating substrate 11, and the gate insulating film 4 is disposed on the top layer of the gate electrode 3c so as to cover the gate electrode 3c. The semiconductor layer 2b having the channel region is disposed on the top layer of the gate insulating film 4 so as to partially overlap the gate electrode 3c. An ohmic contact layer 7c formed of a doped silicon film and the source electrode 6d in the source and drain electrodes 6d and 6e are laminated at one end of the semiconductor layer 2b, and an ohmic contact layer 7d formed of a doped silicon film and the drain electrode 6e in the source and drain electrodes 6d and 6e are laminated at the other end of the semiconductor layer 2b. The passivation film 8 is disposed on the top layer of the source and drain electrodes 6d and 6e. A relay electrode 9b formed of an ITO film is disposed on the top layer of the passivation film 8. The relay electrode 9b is electrically connected to the drain electrode 6e via a contact hole 82 defined in the passivation film 8, and is electrically connected to the gate electrode 3c via a contact hole 83 defined in the passivation film 8 and the gate insulating film 4.

The source and drain electrodes, the semiconductor layers, and the gate electrodes of the bidirectional diode elements Di are made of the same materials as those of the pixel transistors 1c, and are disposed between the same pairs of layers as those of the pixel transistors 1c. The relay electrodes 9b of the bidirectional diode elements Di are made of the same material as that of the pixel electrodes 9a of the pixel transistors 1c, and are disposed on the same layer as the pixel electrodes 9a of the pixel transistors 1c. The bidirectional diode elements Di and the pixel transistors 1c can therefore be fabricated using a common process.

### Structure of Switching Element 1d

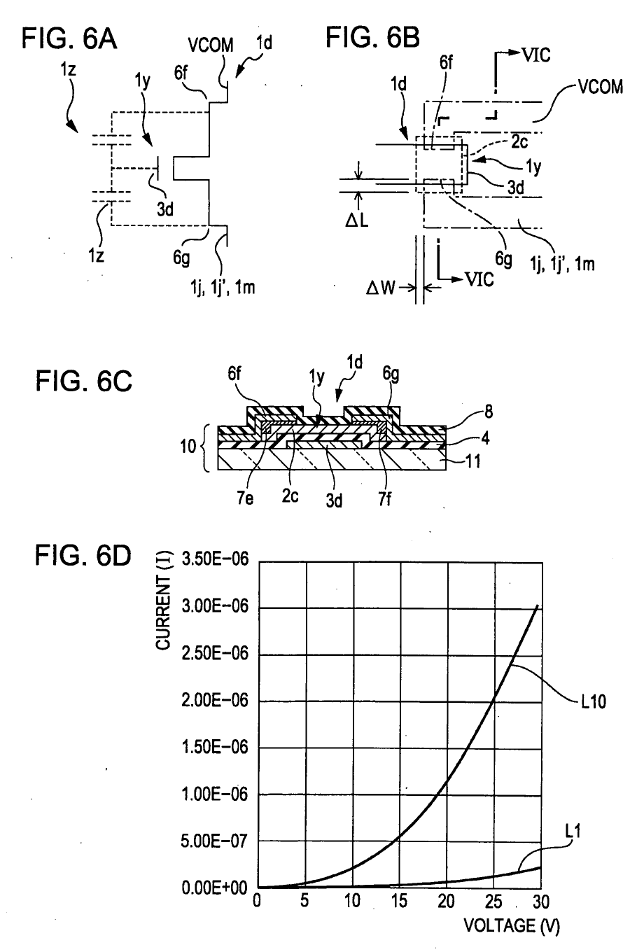

FIGS. 6A and 6B are an equivalent circuit diagram and a plan view of each of the switching elements 1d disposed on the element substrate 10, respectively. FIG. 6C is a cross-sectional view taken along a line VIC-VIC of FIG. 6B, and FIG. 6D is a graph showing the I-V characteristic of the switching element 1d.

As shown in FIGS. 6A, 6B, and 6C, the switching element 1d includes an MIS-type semiconductor element 1y including a pair of source and drain electrodes 6f and 6g, a semiconductor layer 2c having a channel region, and a gate electrode 3d facing the channel region with the gate insulating film 4 disposed therebetween. In the first embodiment, the drain electrodes 6g of the semiconductors elements 1y are connected to the sensor signal lines 1j and 1j′ and the gate-off wiring line 1m, and the source electrodes 6f are connected to the common wiring line VCOM. The gate electrodes 3d are electrically connected to the control wiring line 1n for setting the semiconductor elements 1y to be in the non-conducting state.

As shown in FIG. 6B, the semiconductor element 1y includes overlapping portions ΔW and ΔL where the source and drain electrodes 6f and 6g, the semiconductor layer 2c, and the gate electrode 3d overlap one another. Due to the overlapping portions ΔW and ΔL, as shown in FIG. 6A, parasitic capacitances 1z are generated between the source electrode 6f and the gate electrode 3d and between the drain electrode 6g and the gate electrode 3d.

The cross-sectional structure of the switching element 1d with the above-described structure will be described with reference to FIG. 6C. As shown in FIG. 6C, in the switching element 1d (the semiconductor element 1y), as in each of the pixel transistors 1c, the gate electrode 3d is disposed on the insulating substrate 11, and the gate insulating film 4 is disposed on the top layer of the gate electrode 3d so as to cover the gate electrode 3d. The semiconductor layer 2c having the channel region is disposed on the top layer of the gate insulating film 4 so as to partially overlap the gate electrode 3d. An ohmic contact layer 7e formed of a doped silicon film and the source electrode 6f in the source and drain electrodes 6f and 6g are laminated at one end of the semiconductor layer 2c, and an ohmic contact layer 7f formed of a doped silicon film and the drain electrode 6g in the source and drain electrodes 6f and 6g are laminated at the other end of the semiconductor layer 2c. The passivation film 8 is disposed on the top layer of the source and drain electrodes 6f and 6g.

The source and drain electrodes, the semiconductor layers, and the gate electrodes of the switching elements 1d are made of the same materials as those of the bidirectional diode elements Di and the pixel transistors 1c, and are disposed between the same pairs of layers as those of the bidirectional diode elements Di and the pixel transistors 1c. The switching elements 1d, the bidirectional diode elements Di, and the pixel transistors 1c can therefore be fabricated using a common process.

Each of the switching elements 1d is a floating-gate transistor in which the source and drain electrodes 6f and 6g are not short-circuited with the gate electrode 3d. However, due to the parasitic capacitances 1z between the gate electrodes 3d and the source electrodes 6f and between the gate electrodes 3d and the drain electrodes 6g, when a high voltage is applied, the source electrode 6f and the drain electrode 6g are brought into the conducting state, and static electricity can be discharged to the common wiring line VCOM. FIG. 6D shows the I-V characteristic of the switching element 1d (indicated by a curve L1) and the I-V characteristic of the bidirectional diode element Di shown in FIGS. 5A to 5C (indicated by a curve L10). Also in the switching element 1d, when a high voltage V caused by static electricity is applied between the source electrode 6f and the drain electrode 6g, the source electrode 6f and the drain electrode 6g are brought into the conducting state to discharge the static electricity to the common wiring line VCOM. That is, the voltage V applied to both terminals of the switching element 1d is capacitively divided by the parasitic capacitances 1z. As a result, a voltage of V/2 is applied to the gate electrode 3d. The switching element 1d therefore operates as an electrostatic protection element when a high voltage such as static electricity is applied. Since no connection using a relay electrode is required unlike the bidirectional diode element Di shown in FIGS. 5A to 5C, the switching element 1d can be finished at a relatively early stage of the manufacturing process, and static electricity generated thereafter can be discharged. The sensor elements 1f and 1f′ can therefore be protected against static electricity at a relatively early stage of the manufacturing process.

In addition, the control wiring line 1n for setting the semiconductor elements 1y to be in the non-conducting state is electrically connected to the gate electrode 3d of the semiconductor element 1y in the switching element 1d. Therefore, by applying an off-voltage to the gate electrode 3d via the control wiring line 1n, the semiconductor element 1y can be completely brought into the non-conducting state.

### Structure of Sensor Elements 1f and 1f′

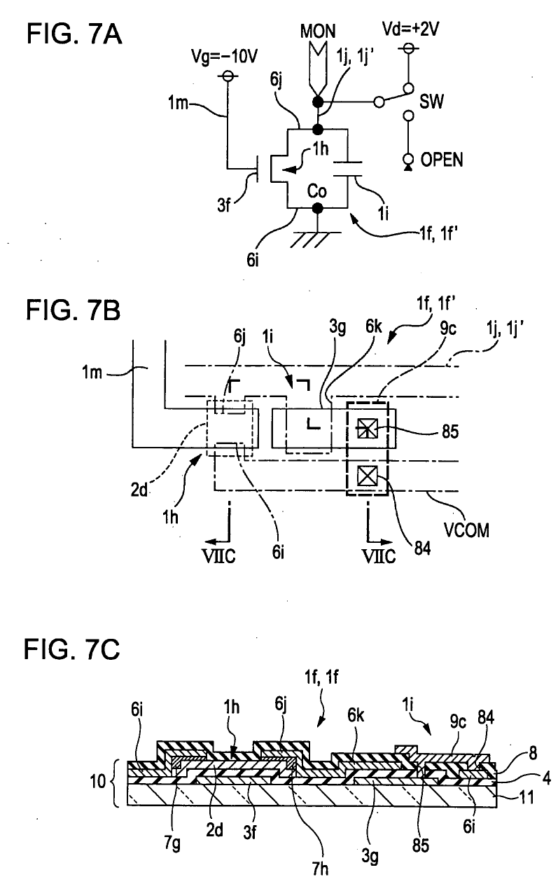

FIGS. 7A and 7B are an equivalent circuit diagram and a plan view of each of the sensor elements 1f and 1f′ defined on the element substrate 10, respectively, and FIG. 7C is a cross-sectional view taken along a line VIIC-VIIC of FIG. 7B. As shown in FIGS. 7A, 7B, and 7C, the sensor element 1f or 1f′ includes an MIS-type semiconductor element 1h including a pair of source and drain electrodes 6i and 6j, a semiconductor layer 2d having a channel region, and a gate electrode 3f facing the channel region with the gate insulating film 4 disposed therebetween, and a capacitor element 1i electrically connected to the semiconductor element 1h in parallel with each other. The drain electrode 6j of the semiconductor element 1h is connected to the sensor signal line 1j or 1j′, and the source electrode 6i is connected to the common wiring line VCOM. The gate electrode 3f is electrically connected to the gate-off wiring line 1m for setting the semiconductor element 1h to be in the non-conducting state.

The cross-sectional structure of the sensor element 1f or 1f′ with the above-described structure will be described with reference to FIG. 7C. As shown in FIG. 7C, in the sensor element 1f or 1f′, as in each of the pixel transistors 1c, the gate electrode 3f of the semiconductor element 1h is disposed on the insulating substrate 11, and the gate insulating film 4 is disposed on the top layer of the gate electrode 3f so as to cover the gate electrode 3f. The semiconductor layer 2d having the channel region is disposed on the top layer of the gate insulating film 4 so as to partially overlap the gate electrode 3f. An ohmic contact layer 7g formed of a doped silicon film and the source electrode 6i in the source and drain electrodes 6i and 6j are laminated at one end of the semiconductor layer 2d, and an ohmic contact layer 7h formed of a doped silicon film and the drain electrode 6j in the source and drain electrodes 6i and 6j are laminated at the other end of the semiconductor layer 2d. The passivation film 8 is disposed on the top layer of the source and drain electrodes 6i and 6j.

An island-shaped lower electrode 3g is further formed concurrently with the gate electrode 3f so as to be arranged side-by-side with respect to the gate electrode 3f. The island-shaped lower electrode 3g faces an upper electrode 6k extending from the drain electrode 6j. A contact hole 85 passing through the gate insulating film 4 and the passivation film 8 is defined at a position overlapping the lower electrode 3g, and a contact hole 84 passing through the passivation film 8 is defined at a position overlapping the source electrode 6i. A relay electrode 9c formed of an ITO film is further disposed on the top layer of the passivation film 8. The relay electrode 9c is electrically connected to the source electrode 6i and the lower electrode 3g via the contact holes 84 and 85, respectively.

The source and drain electrodes, the semiconductor layers, and the gate electrodes of the sensor elements 1f and 1f′ are made of the same materials as those of the pixel transistors 1c, the bidirectional diode elements Di, and the switching elements 1d, and are disposed between the same pairs of layers as those of the pixel transistors 1c, the bidirectional diode elements Di, and the switching elements 1d. The relay electrodes 9c of the sensor elements 1f and 1f′ are made of the same material as that of the pixel electrodes 9a of the pixel transistors 1c and the relay electrodes 9b of the bidirectional diode elements Di, and are disposed on the same layer as the pixel electrodes 9a of the pixel transistors 1c and the relay electrodes 9b of the bidirectional diode elements Di. The sensor elements 1f and 1f′, the pixel transistors 1c, the bidirectional diode elements Di, and the switching elements 1d can therefore be fabricated using a common manufacturing process.

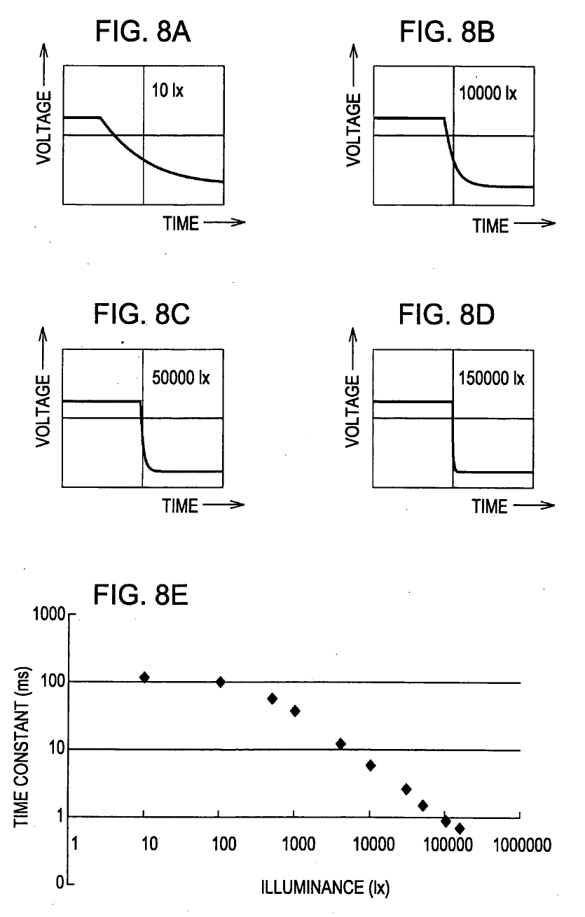

In each of the sensor elements 1f and 1f′ with the above-described structure, when an illuminance is detected, as shown in FIG. 7A, a gate voltage of, for example, −10 V is applied to the gate electrode 3f via the gate-off wiring line 1m to turn off the semiconductor element 1h, and a voltage of, for example, +2 V is applied between the source and drain electrodes 6i and 6j via the sensor signal line 1j or 1j′ to charge the capacitor element 1i. Then, the power supply to the source and drain electrodes 6i and 6j via the sensor signal line 1j or 1j′ is stopped. As a result, the inter-terminal voltage of the sensor element 1f or 1f′ is output from the sensor signal line 1j or 1j′. The inter-terminal voltage changes along a discharge curve obtained when the electric charge charged in the capacitor element 1i is discharged via the semiconductor element 1h, and the amount of charge discharged via the semiconductor elements 1h varies depending on the amount of light received by the semiconductor elements 1h. For example, as shown in the discharge characteristics obtained when the illuminance is 10 1x, 10000 1x, 50000 1x, and 150000 1x shown in FIGS. 8A, 8B, 8C, and 8D, respectively, the higher the illuminance, the more rapidly the discharge occurs. As shown in FIG. 8E, the higher the illuminance, the smaller the time constant for the discharging. Therefore, once a time constant is determined, the illuminance can be detected.

### Manufacturing Method

The liquid crystal device 100 with the above-described structure is manufactured using a known semiconductor process or the like. That is, although a detailed description is omitted, after the gate electrodes 3b and the scanning lines 3a are formed on the insulating substrate 11, the gate insulating film 4, the semiconductor layers 2a, the ohmic contact layers 7a and 7b, and the source and drain electrodes 6b and 6c are formed. At this time, the pixel transistors 1c and the semiconductor elements 1h of the sensor elements 1f and 1f′ have been finished and the switching elements 1d have also been finished. Thus, static electricity generated in the sensor signal lines 1j and 1j′ and the gate-off wiring line 1m after that time can be discharged to the common wiring line VCOM via the switching elements id. The sensor elements 1f can therefore be protected against static electricity.

When the passivation film 8 and the pixel electrodes 9a are formed, the bidirectional diodes Di have been finished. Thus, static electricity generated in the data lines 6a and the scanning line 3a after that time can be discharged to the common wiring line VCOM via the bidirectional diode elements Di. The pixel transistors 1c can therefore be protected against static electricity. After the element substrate 10 is fabricated in this manner, the element substrate 10 and the counter substrate 20 are bonded through the seal 52, and the liquid crystal 50 is injected between the substrates 10 and 20.

Then, the drive ICs 101 and 102 are mounted on the element substrate 10, and the flexible wiring substrate 105 having the sensor-drive IC 103 mounted thereon is connected to the element substrate 10. Thus, the liquid crystal device 100 is finished. The liquid crystal device 100 is incorporated into an electronic apparatus such as a mobile phone.

### Sensing Operation

When the electronic apparatus is used, an image is displayed on the liquid crystal device 100, and the display conditions are optimized according to the illuminance detected by the sensor elements 1f and 1f′. That is, in the liquid crystal device 100, a gate voltage for turning off the semiconductor elements 1h, for example, a voltage of −10 V, is applied to the gate electrodes 3f of the sensor elements 1f and 1f′ from the sensor-drive IC 103 via the gate-off wiring line 1m, and a constant voltage, for example, a voltage of +2 V, is supplied to the sensor elements 1f and 1f′ via the sensor signal lines 1j and 1j′ to charge the capacitor elements 1i. Then, when the supply of the constant voltage to the sensor elements 1f and 1f′ via the sensor signal lines 1j and 1j′ is stopped, the sensor elements 1f and 1f′ output changes in the inter-terminal voltages (discharge curves) of the sensor elements 1f and 1f′ to the sensor-drive IC 103 via the sensor signal lines 1j and 1j′. A time constant is determined on the basis of the output results, and therefore the illuminance is determined. By feeding back the detected illuminance to, for example, a backlight device, the display can be performed under conditions suitable for the ambient illuminance. For example, when the ambient illuminance is high, the intensity of light emission from the backlight device increases accordingly to provide bright display, whereas when the ambient illuminance is low, the intensity of light emission from the backlight device decreases accordingly. Further, a signal level specifying the gray levels of an image may be optimized on the basis of the detected illuminance. The illuminance detection operation of the liquid crystal device 100 is performed at predetermined intervals of time during the use of the electronic apparatus or by a button operation by a user.

During that period, a gate voltage for setting the semiconductor elements 1y to be in the non-conducting state is applied to the gate electrodes 3d of the semiconductor elements 1y used in the switching elements 1d via the control wiring line 1n. The switching elements 1d can therefore be electrically isolated from the sensor signal lines 1j and 1j′.

### Advantages of First Embodiment

As described above, in the liquid crystal device 100 of the first embodiment, since the sensor elements 1f and 1f′ are arranged on the element substrate 10, the illuminance of the environment where the liquid crystal device 100 is placed can be detected using the sensor elements 1f and 1f′. Therefore, an image can be displayed under conditions corresponding to the detected illuminance.

Further, during the manufacturing process of the element substrate 10, the sensor signal lines 1j and 1j′ through which signals are output from the sensor elements 1f and 1f′, and the gate-off wiring line 1m are electrically connected to the common wiring line VCOM via the switching elements 1d. Therefore, static electricity generated on the element substrate 10 during the manufacturing process of the electro-optical device can be discharged to the common wiring line VCOM via the switching elements 1d, and the sensor elements 1f and 1f′ can be protected against static electricity. That is, during the manufacturing process, the gate electrodes 3d of the switching elements 1d connected to the sensor signal lines 1j and 1j′ and the gate-off wiring line 1m are in an electrically floating state. In this state, if a high voltage caused by static electricity is applied between the common wiring line VCOM and the sensor signal lines 1j and 1j′ and the gate-off wiring line 1m, the parasitic capacitances 1z between the source electrodes 6f and gate electrodes 3d of the semiconductor elements 1y allow the applied voltage to be divided, and the divided voltage is applied to the gate electrodes 3d. As a result, the semiconductor elements 1y are brought into the conducting state, and static electricity can be discharged. Further, the switching elements 1d are finished at an early stage of the manufacturing process compared with the bidirectional diode element Di described with reference to FIGS. 5A to 5C, and the static electricity generated thereafter can be discharged. The sensor elements 1f and 1f′ can therefore be protected against static electricity at a relatively early stage of the manufacturing process.

Further, the control wiring line 1n is disposed for the gate electrodes 3d of the semiconductor elements 1y of the switching elements id. Thus, when the liquid crystal device 100 has been finished, a predetermined gate voltage is applied to the gate electrodes 3d from the control wiring line 1n, thereby ensuring that the switching elements 1d can be brought into the non-conducting state so that the switching elements id do not affect the signals output from the sensor elements 1f and 1f′. Therefore, in the case where the sensor signal lines 1j and 1j′ defined on the element substrate 10 are electrically connected to the common wiring line VCOM via the bidirectional diode elements Di to protect the sensor elements 1f and 1f′ against static electricity, high-accuracy detection can be performed using the sensor elements 1f.

### Modification of First Embodiment

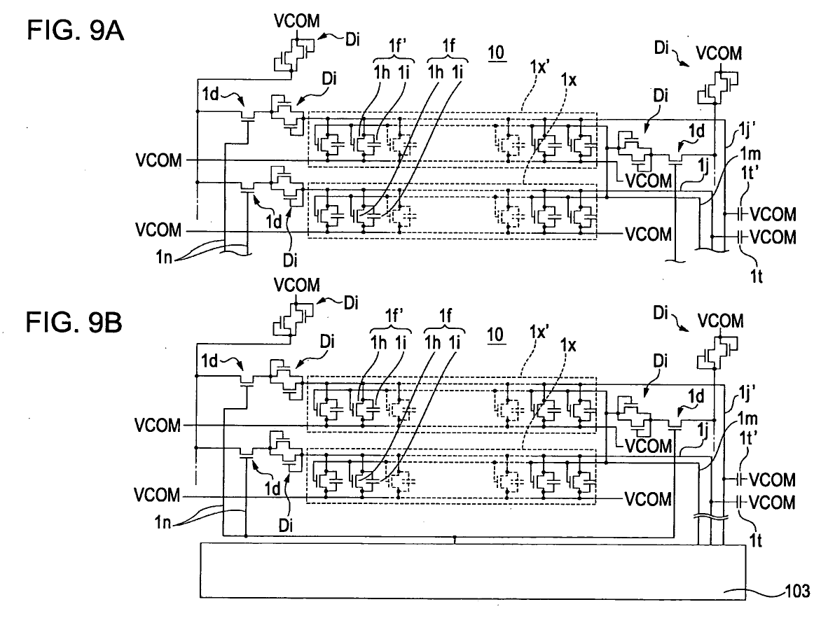

FIGS. 9A and 9B are block diagrams showing the electrical structure of sensor elements and the like disposed on an element substrate of a liquid crystal device according to a modification of the first embodiment of the invention. FIG. 9A shows the state before an external circuit is mounted on the element substrate, and FIG. 9B shows the structure after the external circuit has been mounted. In this modification, the following second embodiment, and the like, since the basic structure is similar to that of the first embodiment described with reference to FIGS. 3A to 4B, the same or similar components as or to those of the first embodiment are represented by the same reference numerals, and a description thereof is omitted.

In the first embodiment, the switching elements 1d are directly connected to the sensor signal lines 1j and 1j′ and the gate-off wiring line 1m. As shown in FIGS. 9A and 9B, the bidirectional diode element Di described with reference to FIGS. 5A to 5C may be arranged between the switching elements 1d and the sensor signal lines 1j and 1j′ and between the switching elements 1d and the gate-off wiring line 1m.

### Second Embodiment

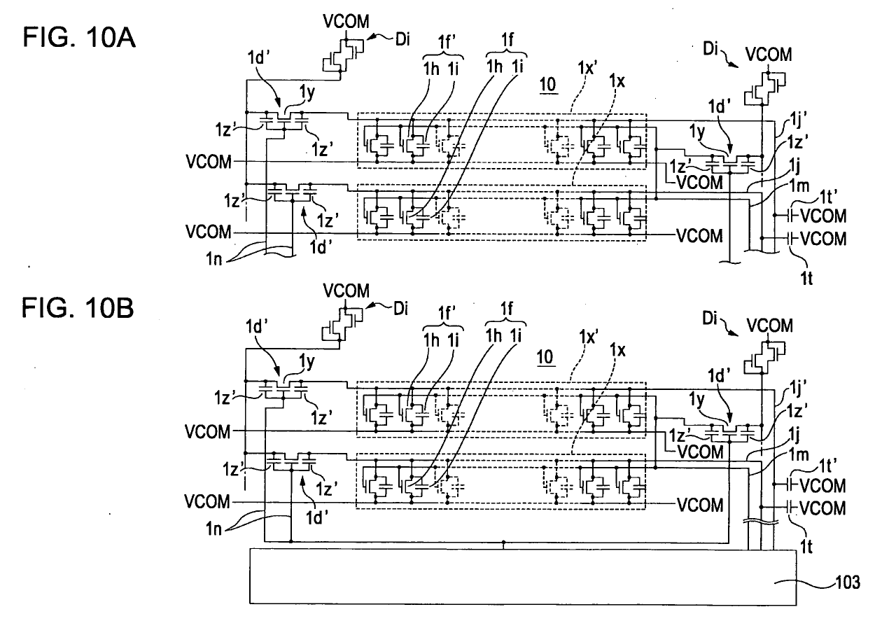

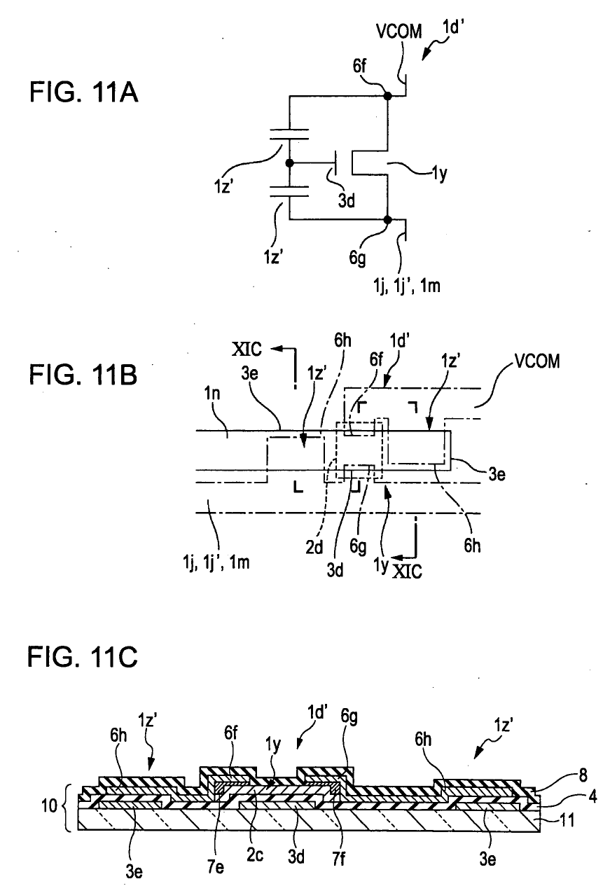

FIGS. 10A and 10B are block diagrams showing the electrical structure of sensor elements and the like disposed on an element substrate 10 of a liquid crystal device according to a second embodiment of the invention. FIG. 10A shows the state before an external circuit is mounted on the element substrate 10, and FIG. 10B shows the structure after the external circuit has been mounted. FIGS. 11A and 11B are an equivalent circuit diagram and a plan view of switching elements 1d′ disposed on the element substrate 10 of the second embodiment, respectively, and FIG. 11C is a cross-sectional view taken along a line XIC-XIC of FIG. 11B.

In the first embodiment, the parasitic capacitances 1z are used for the switching elements 1d. In the second embodiment, as shown in FIGS. 10A, 10B, 11A, 11B, and 11C, each of the switching elements id′ includes a semiconductor element 1y and two capacitor elements 1z′. That is, each of the switching elements 1d′ includes an MIS-type semiconductor element 1y including a pair of source and drain electrodes 6f and 6g, a semiconductor layer 2c having a channel region, and a gate electrode 3d facing the channel region with a gate insulating film 4 disposed therebetween, and capacitor elements 1z′ arranged between the source electrode 6f of the pair of source and drain electrodes 6f and 6g and the gate electrode 3d and between the drain electrode 6g and the gate electrode 3d.

Also in the switching elements 1d′ with the above-described structure, the drain electrodes 6g of the semiconductor elements 1y are connected to sensor signal lines 1j and 1j′ and a gate-off wiring line 1m, and the source electrodes 6f are connected to a common wiring line VCOM. The gate electrodes 3d are electrically connected to a control wiring line 1n for setting the semiconductor elements 1y to be in the non-conducting state.

The cross-sectional structure of each of the switching elements id′ with the above-described structure will be described with reference to FIG. 11C. As shown in FIG. 11C, in the switching element id′, as in each of the pixel transistors 1c, the gate electrode 3d of the semiconductor element 1y is disposed on the insulating substrate 11, and the gate insulating film 4 is disposed on the top layer of the gate electrode 3d so as to cover the gate electrode 3d. The semiconductor layer 2c having the channel region is disposed on the top layer of the gate insulating film 4 so as to partially overlap the gate electrode 3d. An ohmic contact layer 7e formed of a doped silicon film and the source electrode 6f in the source and drain electrodes 6f and 6g are laminated at one end of the semiconductor layer 2c, and an ohmic contact layer 7f formed of a doped silicon film and the drain electrode 6g in the source and drain electrodes 6f and 6g are laminated at the other end of the semiconductor layer 2c. The passivation film 8 is disposed on the top layer of the source and drain electrodes 6f and 6g.

The gate electrode 3d has extending portions to form two lower electrodes 3e. One of the two lower electrodes 3e faces an upper electrode 6h extending from the drain electrode 6g via the gate insulating film 4, and the other lower electrode 3e faces an upper electrode 6h extending from the source electrode 6f via the gate insulating film 4. Thus, the two capacitor elements 1z′ are formed.

The source and drain electrodes, the semiconductor layers, and the gate electrodes of the switching elements 1d′ are made of the same materials as those of the bidirectional diode elements Di and the pixel transistors 1c, and are disposed between the same pairs of layers as those of the bidirectional diode elements Di and the pixel transistors 1c. The switching elements 1d′, the bidirectional diode elements Di, and the pixel transistors 1c can therefore be fabricated using a common process.

In each of the switching elements 1d′ with the above-described structure, as in the switching element 1d described with reference to FIGS. 6A to 6C, the gate electrode 3d is in an electrically floating state. However, since the capacitor elements 1z′ are defined between the gate electrode 3d and the source electrode 6f and between the gate electrode 3 and the drain electrode 6g, the source electrode 6f and the drain electrode 6g are brought into the conducting state when a high voltage is applied. Thus, static electricity can be discharged to the common wiring line VCOM. That is, also in the switching element id′ shown in FIGS. 11A to 11C, when a high voltage V caused by static electricity is applied between the source electrode 6f and the drain electrode 6g, the applied voltage V is capacitively divided by the capacitor elements 1z′. As a result, a voltage of to V/2 is applied to the gate electrode 3d. The switching element id′ therefore operates as an electrostatic protection element when a high voltage such as static electricity is applied. Since no connection using a relay electrode is required unlike the bidirectional diode element Di shown in FIGS. 5A to 5C, the switching element id′ can be finished at a relatively early stage of the manufacturing process, and static electricity generated thereafter can be discharged. The sensor elements 1f and 1f′ can therefore be protected against static electricity at a relatively early stage of the manufacturing process.

Further, the control wiring line 1n is disposed for the gate electrodes 3d of the semiconductor elements 1y in the switching elements id′. Thus, a predetermined gate voltage is applied to the gate electrodes 3d from the control wiring line 1n, thereby ensuring that the switching elements 1d′ can be brought into the non-conducting state so that the switching elements id′ do not affect the signals output from the sensor elements 1f and 1f′. Therefore, in a structure in which the sensor elements 1f and 1f′ defined on the element substrate 10 are protected against static electricity, high-accuracy detection can be performed using the sensor elements 1f.

### Modifications of Second Embodiment

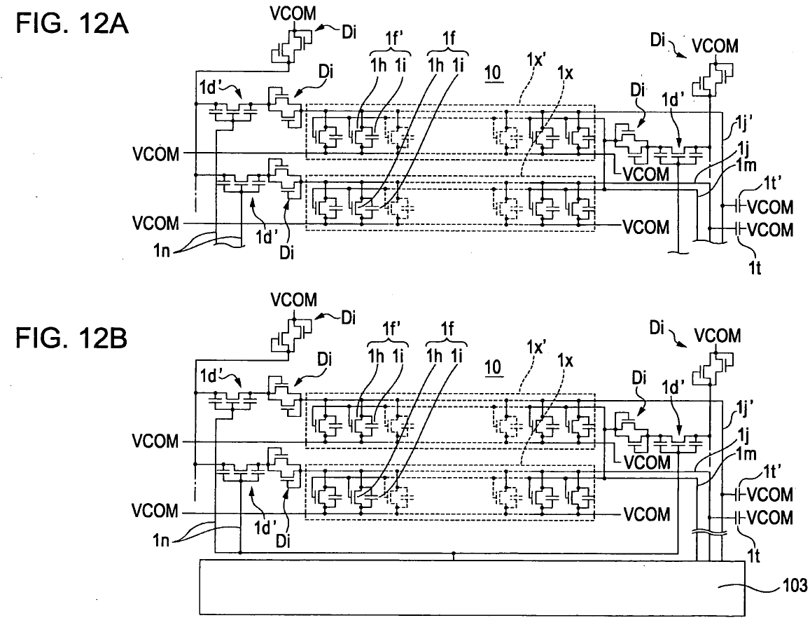

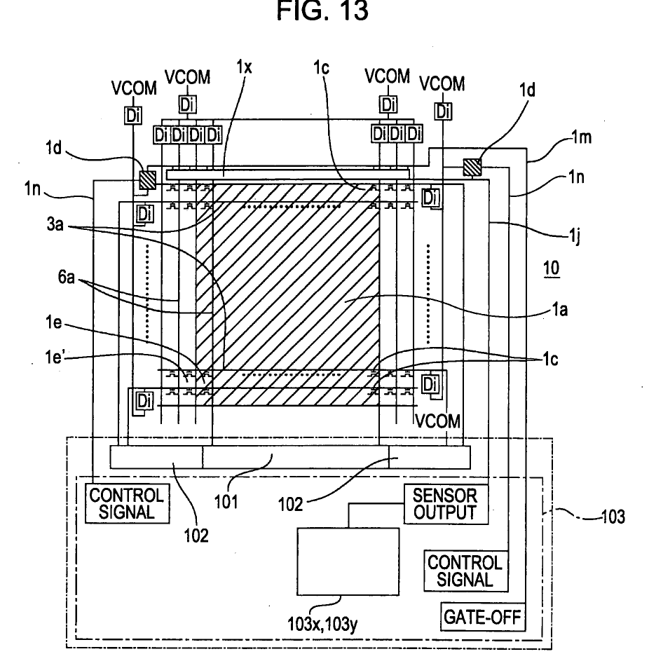

FIGS. 12A and 12B are block diagrams showing the electrical structure of sensor elements and the like disposed on an element substrate of a liquid crystal device according to a modification of the second embodiment of the invention. FIG. 12A shows the state before an external circuit is mounted on the element substrate, and FIG. 12B shows the structure after the external circuit has been mounted.

In the second embodiment, the switching elements id′ are directly connected to the sensor signal lines 1j and 1j′ and the gate-off wiring line 1m. As shown in FIGS. 12A and 12B, the bidirectional diode element Di described with reference to FIGS. 5A to 5C may be disposed between the switching elements id′ and the sensor signal lines 1j and 1j′ and between the switching elements id′ and the gate-off wiring line 1m.

### Another Embodiment

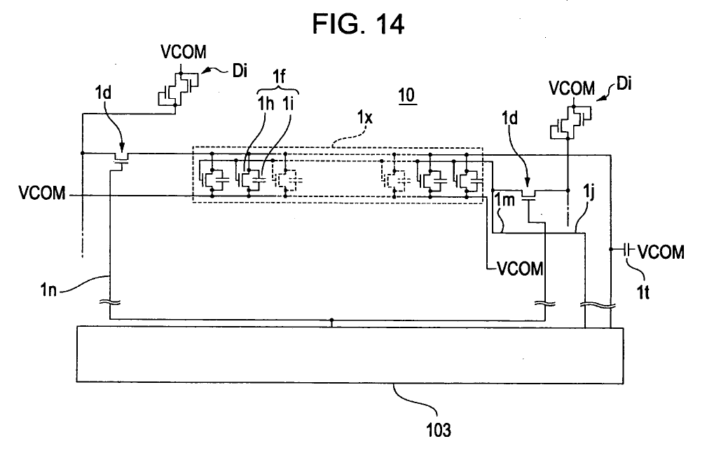

FIG. 13 is a block diagram showing the electrical structure of an element substrate 10 according to another embodiment of the invention, and FIG. 14 is a block diagram showing the electrical structure of sensor elements and the like disposed on the element substrate 10. Since the basic structure of this embodiment is similar to that of the embodiment described with reference to FIGS. 3A to 4B, the same or similar components are represented by the same reference numerals, and a description thereof is omitted.

As shown in FIG. 13, also on the element substrate 10 used in a liquid crystal device of this embodiment, a plurality of data lines (source lines) 6a and scanning lines (gate lines) 3a are arranged in a region corresponding to an image display region 1a (as shown by shading) so that the data lines 6a and the scanning lines 3a orthogonally intersect each other, and a plurality of pixel regions 1e are arranged at the intersections of the data lines 6a and the scanning lines 3a. Pixel transistors 1c for controlling the alignment of the liquid crystal are disposed in the pixel regions 1e, and are formed of MIS-type semiconductor elements (thin-film transistors). The base of the element substrate 10 is formed of an insulating substrate such as a glass substrate. If static electricity is generated in the data lines 6a or the scanning lines 3a during the manufacturing process, the pixel transistors 1c may be damaged by the static electricity. Therefore, a common wiring line VCOM defined on the element substrate 10 is connected to a guard ring (not shown) via the bidirectional diode element Di described with reference to FIGS. 5A to 5C, and electrostatic protection elements each formed of the bidirectional diode element Di are arranged between the common wiring line VCOM and the data lines 6a and between the common wiring line VCOM and the scanning lines 3a.

Also in this embodiment, a sensor-element forming region 1x including a plurality of sensor elements 1f is disposed on the element substrate 10 along an edge of the pixel display region 1a. In this embodiment, a temperature is detected using the sensor elements 1f. and no reference sensor elements are disposed. As described with reference to FIGS. 7A to 7C, each of the sensor elements 1f includes a MIS-type semiconductor element 1h, and a capacitor element 1i electrically connected in parallel with the semiconductor element 1h. The element substrate 10 further includes a sensor signal line 1j for outputting signals from first electrodes (the drain electrodes) of the pairs of source and drain electrodes of the sensor elements 1f. and the sensor signal line 1j is electrically connected to a sensor-drive IC 103. The sensor signal line 1j is electrically connected to the common wiring line VCOM via a noise filter element 1t formed of a capacitor. The element substrate 10 further includes a gate-off wiring line 1m extending from the sensor-drive IC 103 toward the sensor-element forming region 1x, and the gate-off wiring line 1m is electrically connected to the gate electrodes of the sensor elements 1f. Second electrodes (the source electrodes) of the pairs of source and drain electrodes of the sensor elements 1f are electrically connected to the common wiring line VCOM. The element substrate 10 further includes switching elements 1d between the sensor signal line 1j and the common wiring line VCOM and between the gate-off wiring line 1m and the common wiring line VCOM in order to protect the sensor elements 1f against static electricity. The element substrate 10 further includes a control wiring line 1n for supplying a gate voltage setting the semiconductor elements 1y of the switching elements id to be in the non-conducting state to the gate electrodes of the semiconductor elements 1y. The control wiring line 1n extends from the sensor-drive IC 103, and is electrically connected to the gate electrodes of the semiconductor elements 1y.

In the liquid crystal device with the above-described structure, the temperature of the environment where the liquid crystal device is placed is detected using the sensor elements 1f, and an image can be displayed under conditions corresponding to the detected temperature. Further, static electricity generated on the element substrate 10 during the manufacturing process of the element substrate 10 can be discharged to the common wiring line VCOM via the switching elements 1d to protect the sensor elements 1f against static electricity. Since the control wiring line 1n is disposed for the gate electrodes 3d of the semiconductor elements 1y of the switching elements id, a predetermined gate voltage is applied to the gate electrodes 3d from the control wiring line 1n, thereby ensuring that the switching elements 1d can be brought into the non-conducting state so that the switching elements 1d do not affect the signals output from the sensor elements 1f. Therefore, in a structure in which the sensor elements 1f disposed on the element substrate 10 are protected against static electricity, high-accuracy detection can be performed using the sensor elements 1f. The structure of this embodiment may be used in the second embodiment.

### Other Embodiments

While the foregoing embodiments have been given in the context of the transmissive liquid crystal device 100, the invention can be applied to reflective liquid crystal devices or transflective liquid crystal devices. In the foregoing embodiments, the scanning lines and the like are implemented by a multi-layer film formed of an aluminum alloy film and a molybdenum film, and the data lines are implemented by a multi-layer film formed of an aluminum film and a molybdenum film. Those lines can be implemented by any other metal film, or a conductive film such as a silicide film. While in the foregoing embodiments, the semiconductor layers are implemented by an intrinsic amorphous silicon film, any other silicon film may be used.

In the foregoing embodiments, the active-matrix liquid crystal device 100 of the TN mode, the ECB mode, or the VAN mode is employed by way of example. The invention can also be applied to the liquid crystal device 100 (electro-optical device) of the IPS (In-Plane Switching) mode.

The liquid crystal device 100 is merely an example of electro-optical devices of the invention. Examples of such electro-optical devices may include organic electroluminescent (EL) devices and image pickup devices in which a plurality of data lines and a plurality of scanning lines extend on the element substrate 10 so as to orthogonally intersect each other and pixel regions are arranged at the intersections of the data lines and the scanning lines.

### Embodiments of Electronic Apparatus

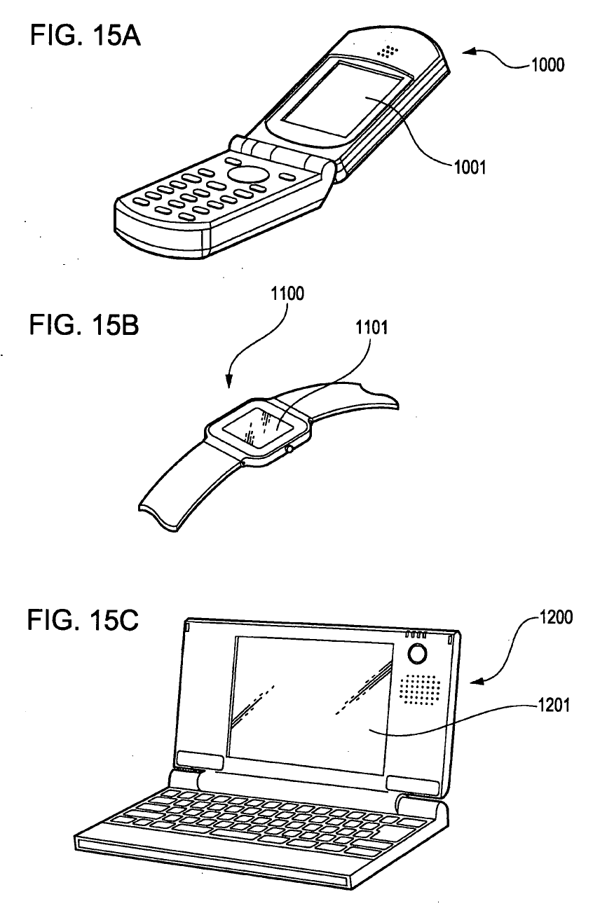

FIGS. 15A to 15C are schematic diagrams of electronic apparatuses including the liquid crystal device 100 according to the invention. The liquid crystal device 100 according to the invention can be incorporated in, for example, a mobile phone 1000 shown in FIG. 15A, a pager 1100 shown in FIG. 15B, and a mobile computer 1200 shown in FIG. 15C. The liquid crystal device 100 forms display units 1001, 1101, and 1201 in those electronic apparatuses. In many cases, those electronic apparatuses are used outdoors. With the use of the liquid crystal device 100 according to the invention, display can be performed under conditions corresponding to the individual use environments. The liquid crystal device 100 according to the invention can also be incorporated as a display device in other apparatuses such as digital still cameras, liquid crystal television sets, viewfinder-type or monitor direction-view type videotape recorders, car navigation systems, electronic organizers, electronic calculators, word processors, workstations, video telephones, point-of-sale (POS) terminals, and apparatuses equipped with a touch panel.

The entire disclosure of Japanese Patent Application No. 2006-153197 is, filed Jun. 1, 2006 is expressly incorporated by reference herein.

What is claimed is:

1. An electro-optical device comprising:
an element substrate,
wherein a plurality of data lines, a plurality of scanning lines, and a plurality of pixel transistors connected to the scanning lines and the data lines are disposed on the element substrate,
wherein a sensor element, a sensor signal line for outputting a signal from the sensor element, and a common wiring line are disposed on the element substrate,
a switching element is disposed between the sensor signal line and the common wiring line, and
a control wiring line for supplying a signal setting the switching element to be in a non-conducting state is disposed for the switching element.

2. The electro-optical device according to claim 1, wherein a bidirectional diode element electrically connected in series with the switching element is disposed between the sensor signal line and the common wiring line.

3. The electro-optical device according to claim 1, wherein the switching element is a semiconductor element including a source electrode, a drain electrode, a semiconductor layer having a channel region, and a gate electrode facing the channel region with a gate insulating film disposed therebetween, the gate electrode being electrically connected to the control wiring line, and
the gate electrode is a floating-gate electrode that is connected to each of the source electrode and the drain electrode via a parasitic capacitance.

4. The electro-optical device according to claim 1, wherein the switching element is a semiconductor element including a source electrode, a drain electrode, a semiconductor layer having a channel region, and a gate electrode facing the channel region with a gate insulating film disposed therebetween, the gate electrode being electrically connected to the control wiring line, and
the gate electrode is a floating-gate electrode that is electrically connected to each of the source electrode and the drain electrode via a capacitor element.

5. The electro-optical device according to claim 4, wherein the capacitor element in the switching element is formed by arranging each of the source electrode and the drain electrode so as to face the gate electrode with an insulation film disposed therebetween.

6. The electro-optical device according to claim 3, wherein:
the sensor element includes
a semiconductor element including a source electrode, a drain electrode, a semiconductor layer having a channel region, and a gate electrode facing the channel region with the gate insulating film disposed therebetween, and
a capacitor element electrically connected to the semiconductor element; and
after the capacitor element is charged, a state quantity is detected on the basis of a characteristic of discharging performed via the semiconductor element of the sensor element.

7. The electro-optical device according to claim 6, wherein:
the source electrode, the drain electrode, the semiconductor layer, and the gate electrode of the switching element are made of the same materials as the materials of the source electrode, the drain electrode, the semiconductor layer, and the gate electrode of the sensor element, respectively; and
a pair of layers between which the source electrode, the drain electrode, the semiconductor layer, or the gate electrode of the switching element is disposed is the same as a pair of layers between which the source electrode, the drain electrode, the semiconductor layer, or the gate electrode of the sensor element is disposed, respectively.

8. The electro-optical device according to claim 6, wherein the channel region of the sensor element is formed of an amorphous silicon film.

9. The electro-optical device according to claim 1, wherein the sensor element is an optical sensor.

10. The electro-optical device according to claim 1, wherein the sensor element is a temperature sensor.

11. The electro-optical device according to claim 3, wherein:
each of the pixel transistors includes
a source electrode, a drain electrode, a semiconductor layer having a channel region, and a gate electrode facing the channel region with the gate insulating film disposed therebetween,
the source electrodes, the drain electrodes, the semiconductor layers, and the gate electrodes of the pixel transistors are made of the same materials as the materials of the source electrode, the drain electrode, the semiconductor layer, and the gate electrode of the switching element, respectively; and
a pair of layers between which the source electrodes, the drain electrodes, the semiconductor layers, and the gate electrodes of the pixel transistors are disposed is the same as a pair of layers between which the source electrode, the drain electrode, the semiconductor layer, or the gate electrode of the switching element is disposed, respectively.

12. An electronic apparatus comprising the electro-optical device according to claim 1.
